(19) United States
(12) Patent Application Publication
(10) Pub. No.: US 2023/0164954 A1
(43) Pub. Date: May 25, 2023

(54) HEAT DISSIPATION STRUCTURE AND ELECTRONIC DEVICE

(71) Applicant: CLEVO CO., NEW TAIPEI CITY (TW)

(72) Inventors: WEI-CHENG LIAO, NEW TAIPEI CITY (TW); BO-XUAN CHEN, NEW TAIPEI CITY (TW); JUNG-CHUN CHEN, NEW TAIPEI CITY (TW)

(21) Appl. No.: 17/969,799

(22) Filed: Oct. 20, 2022

(30) Foreign Application Priority Data
Nov. 19, 2021 (TW) 110213769

(51) Int. Cl. H05K 7/20; G06F 1/20

(52) U.S. Cl. CPC H05K 7/2039; G06F 1/203

(57) ABSTRACT

A heat dissipation structure and an electronic device are provided. The heat dissipation structure includes a first plate body, a second plate body, and m thermally conductive members. The m thermally conductive members are arranged between the first plate body and the second plate body. Among the m thermally conductive members, n thermally conductive members are arranged along at least one of a length direction of the first plate body and a length direction of the second plate body, or a width direction of the first plate body and a length direction of the second plate body, and m≥n≥2.

### CROSS-REFERENCE TO RELATED PATENT APPLICATION

This application claims the benefit of priority to Taiwan Patent Application No. 110213769, filed on Nov. 19, 2021. The entire content of the above identified application is incorporated herein by reference.

Some references, which may include patents, patent applications and various publications, may be cited and discussed in the description of this disclosure. The citation and/or discussion of such references is provided merely to clarify the description of the present disclosure and is not an admission that any such reference is “prior art” to the disclosure described herein. All references cited and discussed in this specification are incorporated herein by reference in their entireties and to the same extent as if each reference was individually incorporated by reference.

### FIELD OF THE DISCLOSURE

The present disclosure relates to a heat dissipation structure, and more particularly to a heat dissipation structure including a plurality of heat pipes.

### BACKGROUND OF THE DISCLOSURE

With the advancement of technology, the number of electronic components accommodated in the electronic device is increasing steadily, which is accompanied by an increase in the heat generated during the operation of the electronic components. Therefore, the heat dissipation problem has become an urgent problem for the electronic device manufacturers.

Conventional vapor chambers have excellent thermal conductivity in two dimensions, which can quickly convert a point heat source into a surface heat source. However, their complex structure and complicated manufacturing process result in longer mass production time and high cost.

Heat pipes also have excellent thermal conductivity. However, the heat pipes come in contact with the heat generating source in a small area. In addition, longer heat pipes not only require special manufacturing processes and are costly, but the thermal conductivity thereof also decreases rapidly after a certain length.

Therefore, how to improve a structural design of a heat dissipation structure so as to overcome the above issues, has become one of the important issues to be addressed in the related field.

### SUMMARY OF THE DISCLOSURE

In response to the above-referenced technical inadequacies, the present disclosure provides a heat dissipation structure and an electronic device.

In one aspect, the present disclosure provides a heat dissipation structure, which includes a first plate body, a second plate body, and m thermally conductive members. The m thermally conductive members are disposed between the first plate body and the second plate body. n thermally conductive members of the m thermally conductive members are arranged along at least one of a length direction of the first plate body and a length direction of the second plate body, and a width direction of the first plate body and a length direction of the second plate body, and m≥n≥2.

In certain embodiments, the first plate body and the second plate body are made of a same material or different materials.

In certain embodiments, the first plate body is made of copper, copper alloy, aluminum, aluminum alloy, gold, gold alloy, silver, or silver alloy.

In certain embodiments, the second plate body is made of copper, copper alloy, aluminum, aluminum alloy, gold, gold alloy, silver, or silver alloy.

In certain embodiments, the first plate body is made of copper, copper alloy, aluminum, aluminum alloy, gold, gold alloy, silver, or silver alloy, and the second plate body is made of copper, copper alloy, aluminum, aluminum alloy, gold, gold alloy, silver, or silver alloy.

In certain embodiments, the m thermally conductive members are fixedly connected between the first plate body and the second plate body by welding.

In certain embodiments, the n thermally conductive members are arranged along the length direction of the first plate body and the length direction of the second plate body, the rest of the m thermally conductive members are arranged along the width direction of the first plate body and the width direction of the second plate body, and m≥n≥2.

In another aspect, the present disclosure provides an electronic device, which includes at least one heat generating source and at least one dissipation structure. The at least one dissipation structure includes a first plate body, a second plate body, and m thermally conductive members, and one end of at least one of the m thermally conductive members is arranged adjacent to the at least one heat generating source. The m thermally conductive members are disposed between the first plate body and the second plate body. n thermally conductive members of the m thermally conductive members are arranged along at least one of a length direction of the first plate body and a length direction of the second plate body, and a width direction of the first plate body and a length direction of the second plate body, and m≥n≥2.

In certain embodiments, the at least one heat generating source is a central processing unit (CPU), a graphics processing unit (GPU), a microcontroller (MCU), a microprocessor (MPU), or an application specific integrated circuit (ASIC).

In certain embodiments, the electronic device further includes at least one heat dissipation member, and another end of the at least one of the m thermally conductive members is connected to the at least one heat dissipation member.

Therefore, one of the beneficial effects of the present disclosure is that, in the heat dissipation structure provided by the present disclosure, by virtue of “the m thermally conductive members been disposed between the first plate body and the second plate body” and “the thermally conductive members of the m thermally conductive members are arranged along at least one of the length direction of the first plate body and the length direction of the second plate body, and the width direction of the first plate body and the length direction of the second plate body, and m≥n≥2,” heat can be continuously conducted, and a structural strength of an overall heat dissipation structure can be enhanced, so that redesign and manufacture of an elongated heat pipe is not needed. Therefore, the cost can be reduced and a problem of poor thermal conductivity of elongated heat pipe can be solved.

These and other aspects of the present disclosure will become apparent from the following description of the embodiment taken in conjunction with the following drawings and their captions, although variations and modifications therein may be affected without departing from the spirit and scope of the novel concepts of the disclosure.

### BRIEF DESCRIPTION OF THE DRAWINGS

The described embodiments may be better understood by reference to the following description and the accompanying drawings, in which:

FIG. 1 is a schematic view of a heat dissipation structure in use according to the present disclosure;

FIG. 2 is a schematic exploded view of a heat dissipation structure according to a first embodiment of the present disclosure;

FIG. 3 is a schematic exploded view of a heat dissipation structure according to a second embodiment of the present disclosure; and

FIG. 4 is a schematic exploded view of a heat dissipation structure according to a third embodiment of the present disclosure.

### DETAILED DESCRIPTION OF THE EXEMPLARY EMBODIMENTS

The present disclosure is more particularly described in the following examples that are intended as illustrative only since numerous modifications and variations therein will be apparent to those skilled in the art. Like numbers in the drawings indicate like components throughout the views. As used in the description herein and throughout the claims that follow, unless the context clearly dictates otherwise, the meaning of “a”, “an”, and “the” includes plural reference, and the meaning of “in” includes “in” and “on”. Titles or subtitles can be used herein for the convenience of a reader, which shall have no influence on the scope of the present disclosure.

The terms used herein generally have their ordinary meanings in the art. In the case of conflict, the present document, including any definitions given herein, will prevail. The same thing can be expressed in more than one way. Alternative language and synonyms can be used for any term(s) discussed herein, and no special significance is to be placed upon whether a term is elaborated or discussed herein. A recital of one or more synonyms does not exclude the use of other synonyms. The use of examples anywhere in this specification including examples of any terms is illustrative only, and in no way limits the scope and meaning of the present disclosure or of any exemplified term. Likewise, the present disclosure is not limited to various embodiments given herein. Numbering terms such as “first”, “second” or “third” can be used to describe various components, signals or the like, which are for distinguishing one component/signal from another one only, and are not intended to, nor should be construed to impose any substantive limitations on the components, signals or the like.

### First Embodiment

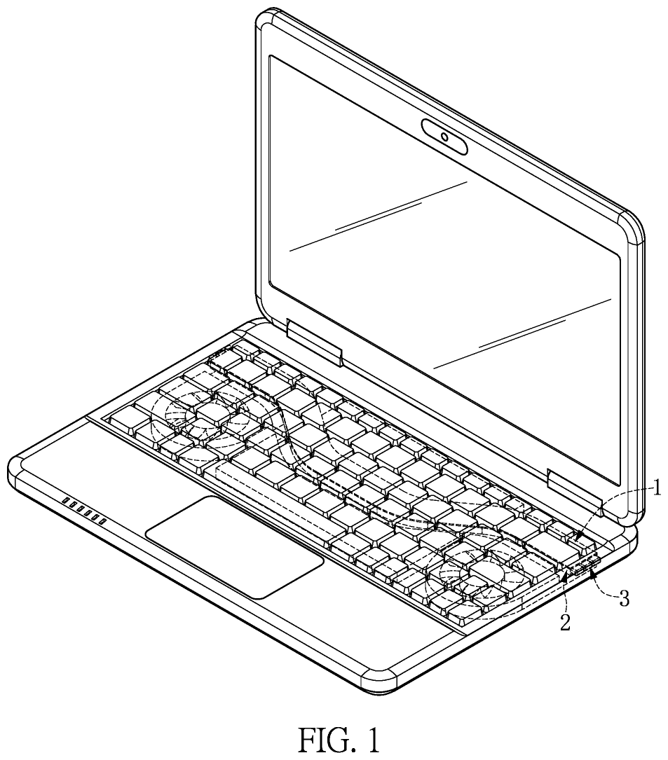

Referring to FIG. 1 to FIG. 4, a first embodiment of the present disclosure provides a dissipation structure, which includes a first plate body 1, a second plate body 2, and a plurality of thermally conductive members 3.

As shown in FIG. 1, the dissipation structure S of the present disclosure can be applied to an electronic device with a heat generating source, such as a desktop computer, a laptop computer, a tablet, and a mobile phone, but the present disclosure is not limited thereto. Further, the heat generating source of the electronic device can be can be a central processing unit (CPU), a graphics processing unit (GPU), a microcontroller (MCU), a microprocessor (MPU), or an application specific integrated circuit (ASIC), but the present disclosure is not limited thereto.

A material of the first plate body 1 can be metal or non-metal with highly thermal conductivity. In one particular embodiment, the material of the first plate body 1 is metal with highly thermal conductivity, such as, but not limited to, copper, copper alloy, aluminum, aluminum alloy, gold, gold alloy, silver, and silver alloy.

A material of the second plate body 2 can be metal or non-metal with highly thermal conductivity. In one particular embodiment, the material of the second plate body 2 is metal with highly thermal conductivity, such as, but not limited to, copper, copper alloy, aluminum, aluminum alloy, gold, gold alloy, silver, and silver alloy.

Further, the material of the first plate body 1 and the material of the second plate body 2 can be the same or different. In one particular embodiment, the material of the first plate body 1 and the material of the second plate body 2 are the same, and each of the material of the first plate body 1 and the material of the second plate body 2 is copper.

On the other hand, a shape and a size of each of the first plate body 1 and the second plate body 2 can be the same or different, and can be adjusted according to the user's demand or the practical applications. Further, the shape and the size of each of the first plate body 1 and the second plate body 2 can also be adjusted according to an arrangement of the plurality of thermally conductive members 3, as long as the first plate body 1 and the second plate body 2 can correspondingly and completely cover an upper surface and a lower surface of each of the plurality of thermally conductive members 3. In one particular embodiment, the shape of the first plate body 1 is the same as the shape of the second plate body 2, and the size of the first plate body 1 is the same as the size of the second plate body 2.

Each of the plurality of thermally conductive members 3 is disposed between the first plate body 1 and the second plate body 2. In the present embodiment, the thermally conductive member 3 is a heat pipe, but the present disclosure is not limited thereto. In addition, the plurality of thermally conductive members 3 are correspondingly and fixedly connected the first plate body 1 and the second plate body 2 by welding, so that heat can be continuously conducted, and a structural strength of the overall heat dissipation structure S can be enhanced.

Further, the thermally conductive member 3 has a first end 31, a second end 32, and a connection part 33, which is connected between the first end 31 and the second end 32. In addition, any one end of the thermally conductive member 3 can be used as a heated end, and another end of the thermally conductive member 3 can be used as a heat dissipation end, that is, the first end 31 or the second end 32 can be used as the heated end, in which case the second end 32 or the first end 31 can be used as the heat dissipation end.

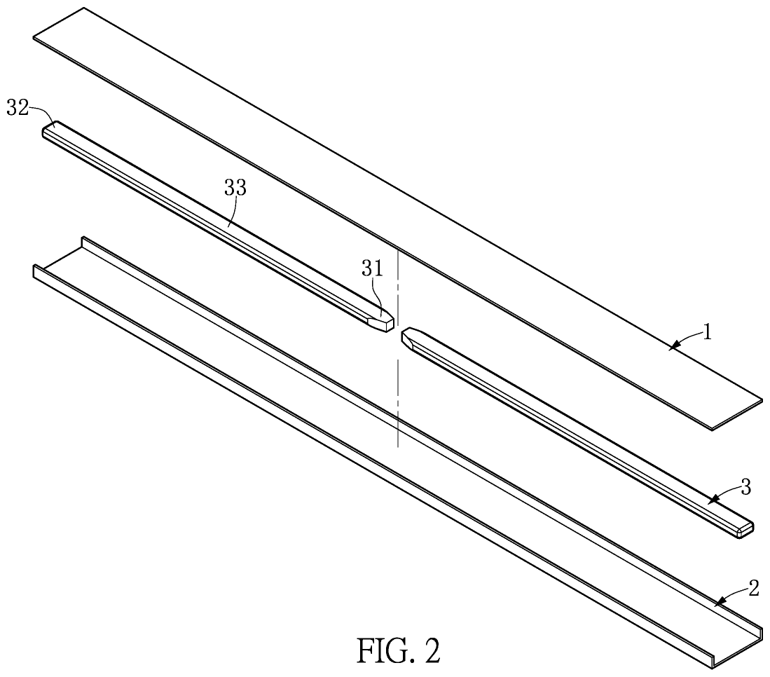

In the present embodiment, as shown in FIG. 2, a number of the plurality of the thermally conductive members 3 is two, the two thermally conductive members 3 are disposed between the first plate body 1 and the second plate body 2 along a length direction of the first plate body 1 and a length direction of the second plate body 2, and the two thermally conductive members 3 are spaced apart at a predetermined distance. The two thermally conductive members 3 can be arranged in such a way that the two first ends 32 respectively of the two thermally conductive members 3 are adjacent to each other, that is, the heat generating source can be arranged between the two thermally conductive members 3, so that the heat generated by the heat generating source is correspondingly transmitted to the two second ends 32 through the two first ends 31 in opposite directions. On the other hand, the first end 31 of one of the two thermally conductive members 3 can be adjacent to the second end 32 of another one of the two thermally conductive members 3 (not shown in the figures), that is, the heat generating source is arranged near the first end 31 of the another one of the two thermally conductive members 3, so that the heat generated by the heat generating source is transmitted sequentially through the first end 31 of the another one of the two thermally conductive members 3, the connection part 33 of the another one of the two thermally conductive members 3, the second end 32 of the another one of the two thermally conductive members 3, the first end of the one of the two thermally conductive members 3, and the connection part 33 of the one of the two thermally conductive members 3, to the second end 32 of the one of the two thermally conductive members 3. In addition, the predetermined distance can be adjusted according to the user's demand or the practical applications, so as to obtain better thermal conductivity.

Further, the number of the plurality of the thermally conductive members 3 can be at least two. The plurality of the thermally conductive members 3 are disposed between the first plate body 1 and the second plate body 2 along the length direction of the first plate body 1 and the length direction of the second plate body 2, and the plurality of the thermally conductive members 3 are spaced apart at the predetermined distance. In a case where the heat dissipation structure needs to be disposed across a great distance, the conventional heat pipes can be directly used to form an elongated heat dissipation structure by bridging two, three, four, or more of the conventional heat pipes between the first plate body 1 and the second plate body 2. In addition, a shape of the overall heat dissipation structure can be adjusted according to a disposition position and a structure around the heat generating source, so that redesign and manufacture of the elongated heat pipe is not needed. Therefore, the cost can be reduced and a problem of poor thermal conductivity of elongated heat pipe can be solved.

In addition, each of the plurality of thermally conductive members 3 can be of the same or different size, and the present disclosure is not limited thereto.

However, the aforementioned details are disclosed for exemplary purposes only, and are not meant to limit the scope of the present disclosure.

### Second Embodiment

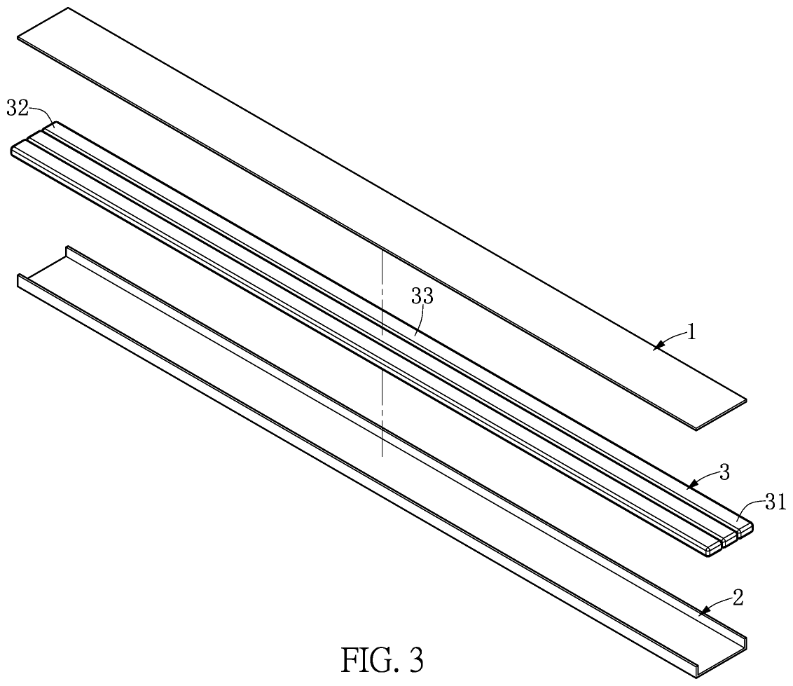

Referring to FIG. 3, FIG. 3 is a schematic exploded view of a heat dissipation structure according to a second embodiment of the present disclosure. The main difference between the second embodiment and the first embodiment is that, the plurality of the thermally conductive members 3 of the heat dissipation structure S of the second embodiment are disposed between the first plate body 1 and the second plate body 2 along a width direction of the first plate body 1 and a width direction of the second plate body 2. In addition, it should be noted that other configurations of the heat dissipation structures S of the second embodiment are similar to those of the first embodiment described above, and will not be iterated herein.

In the present embodiment, as shown in FIG. 3, the number of the plurality of thermally conductive members 3 is three, and the three thermally conductive members 3 are disposed between the first plate body 1 and the second plate body 2 along the width direction of the first plate body 1 and the width direction of the second plate body 2. In such the arrangement, one end of the heat dissipation structure S is the first end 31 of one of the plurality of thermally conductive members 3, and another end of the heat dissipation structure S is the second end 32 of another one of the plurality of thermally conductive members 3. A user may determine the disposition position of the heat dissipation structure S relative to the heat generating source according to the practical applications.

Further, each of the three thermally conductive members 3 can be of the same or different size, that is, one end of each of the three thermally conductive members 3 can be flush or not flush when the three thermally conductive members 3 are disposed between the first plate body 1 and the second plate body 2, which can be adjusted according to the user's demand and the practical applications, but the present disclosure is not limited thereto.

However, the aforementioned details are disclosed for exemplary purposes only, and are not meant to limit the scope of the present disclosure.

### Third Embodiment

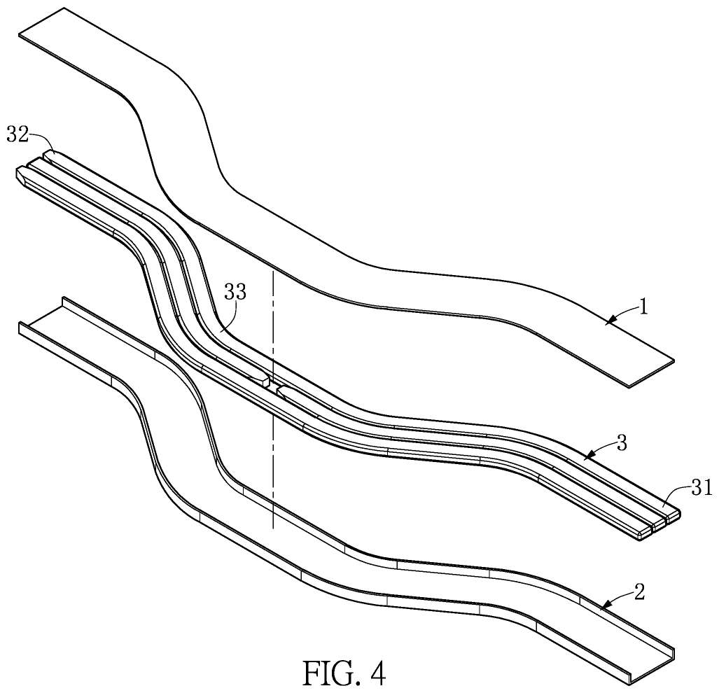

Referring to FIG. 4, FIG. 4 is a schematic exploded view of a heat dissipation structure according to a third embodiment of the present disclosure. The main difference between the third embodiment, the first embodiment and the second embodiment is that, a part of the plurality of thermally conductive members 3 of the heat dissipation structure S of the third embodiment are disposed between the first plate body 1 and the second plate body 2 along the length direction of the first plate body 1 and the length direction of the second plate body 2, and another part of the plurality of thermally conductive members 3 are disposed between the first plate body 1 and the second plate body 2 along the width direction of the first plate body 1 and the width length of the second plate body 2. In addition, it should be noted that other configurations of the heat dissipation structures S of the third embodiment are similar to those of the first embodiment described above, and will not be iterated herein.

In the present embodiment, as shown in FIG. 4, the number of the plurality of the thermally conductive members 3 is four, two thermally conductive members 3 are disposed between the first plate body 1 and the second plate body 2 along the length direction of the first plate body 1 and the length direction of the second plate body 2, and the two thermally conductive members 3 are spaced apart at the predetermined distance. In addition, another two thermally conductive members 3 are arranged outside of the two thermally conductive members 3. That is, if the two thermally conductive members 3 are regarded as one thermally conductive member 3 that is formed by bridging, the another two thermally conductive members 3 and the thermally conductive member 3 that is formed by bridging arranged therebetween are disposed between the first plate body 1 and the second plate body 2 along the width direction of the first plate body 1 and the width direction of the second plate body 2.

Further, as shown in FIG. 4, which is to be read in conjunction with FIG. 1, a shape of the heat dissipation structure S can be adjusted according to the disposition position and the structure around the heat generating source. Accordingly, the shape of the heat dissipation structure S can be, for example, but not limited to, a straight line, a curved shape, an arc, a circle, a square, a triangle, a polygon, a U-shape, and a V-shape. In the present embodiment, the shape of the heat dissipation structure S is the V-shape, but the present disclosure is not limited thereto.

In addition, each of the plurality of thermally conductive members 3 can be of the same or different size, and the present disclosure is not limited thereto.

However, the aforementioned details are disclosed for exemplary purposes only, and are not meant to limit the scope of the present disclosure.

### Fourth Embodiment

According to the above, as shown in FIG. 1, the present disclosure also provides an electronic device, which includes at least one heat generating source (not shown in the figures) at least one heat dissipation structure S as described in any of the first to third embodiments. The electronic device can be a desktop computer, a laptop computer, a tablet, and a mobile phone, but the present disclosure is not limited thereto. Further, the at least one heat generating source can be can be a central processing unit (CPU), a graphics processing unit (GPU), a microcontroller (MCU), a microprocessor (MPU), or an application specific integrated circuit (ASIC), but the present disclosure is not limited thereto. The heat dissipation structure S is as described in the first to third embodiments, and will not be reiterated herein.

Further, the heat generating source can be disposed on a carrier substrate, and one end (e.g., the first end 31) of at least one thermally conductive member 3 of the heat dissipation structure S can be disposed adjacent to the heat generating source, so that heat generated by the heat generating source is transmitted through the heat dissipation structure S to another area other than an area where the heat generated is arranged. In addition, the shape of the heat dissipation structure S can be adjusted according to the disposition position and the structure around the heat generating source. The shape of the heat dissipation structure S can be, for example, but not limited to, the straight line, the curved shape, the arc, the circle, the square, the triangle, the polygon, the U-shape, and the V-shape.

Further, another end (e.g., the second end 32) of the at least one thermally conductive member 3 of the heat dissipation structure S can be disposed near or connected to at least one heat dissipation member (not shown in the figures), so as to dissipate the heat generated by the heat generating source. The at least one heat dissipation member can be a heat dissipation fin, a heat sink, or a water cooling module, as long as the heat dissipation effect can be achieved in the electronic device, but the present disclosure is not limited thereto.

However, the aforementioned details are disclosed for exemplary purposes only, and are not meant to limit the scope of the present disclosure.

### Beneficial Effects of the Embodiments

In conclusion, one of the beneficial effects of the present disclosure is that, in the heat dissipation structure provided by the present disclosure, by virtue of “the m thermally conductive members 3 been disposed between the first plate body 1 and the second plate body 2” and “the n thermally conductive members 3 of the m thermally conductive members 3 are arranged along at least one of the length direction of the first plate body 1 and the length direction of the second plate body 2, and the width direction of the first plate body 1 and the length direction of the second plate body 2, and m≥n≥2,” the heat can be continuously conducted, and the structural strength of the overall heat dissipation structure can be enhanced, so that redesign and manufacture of the elongated heat pipe is not needed. Therefore, the cost can be reduced and the problem of poor thermal conductivity of elongated heat pipe can be solved.

The foregoing description of the exemplary embodiments of the disclosure has been presented only for the purposes of illustration and description and is not intended to be exhaustive or to limit the disclosure to the precise forms disclosed. Many modifications and variations are possible in light of the above teaching.

The embodiments were chosen and described in order to explain the principles of the disclosure and their practical application so as to enable others skilled in the art to utilize the disclosure and various embodiments and with various modifications as are suited to the particular use contemplated. Alternative embodiments will become apparent to those skilled in the art to which the present disclosure pertains without departing from its spirit and scope.

What is claimed is:

1. A heat dissipation structure, comprising:
a first plate body;
a second plate body; and
m thermally conductive members disposed between the first plate body and the second plate body;
wherein n thermally conductive members of the m thermally conductive members are arranged along at least one of a length direction of the first plate body and a length direction of the second plate body, and a width direction of the first plate body and a length direction of the second plate body, and m≥n≥2.

2. The heat dissipation structure according to claim 1, wherein the first plate body and the second plate body are made of a same material or different materials.

3. The heat dissipation structure according to claim 2, wherein the first plate body is made of copper, copper alloy, aluminum, aluminum alloy, gold, gold alloy, silver, or silver alloy.

4. The heat dissipation structure according to claim 2, wherein the second plate body is made of copper, copper alloy, aluminum, aluminum alloy, gold, gold alloy, silver, or silver alloy.

5. The heat dissipation structure according to claim 2, wherein the first plate body is made of copper, copper alloy, aluminum, aluminum alloy, gold, gold alloy, silver, or silver alloy, and the second plate body is made of copper, copper alloy, aluminum, aluminum alloy, gold, gold alloy, silver, or silver alloy.

6. The heat dissipation structure according to claim 1, wherein the m thermally conductive members are fixedly connected between the first plate body and the second plate body by welding.

7. The heat dissipation structure according to claim 1, wherein the n thermally conductive members are arranged along the length direction of the first plate body and the length direction of the second plate body, the rest of the m thermally conductive members are arranged along the width direction of the first plate body and the width direction of the second plate body, and m>n≥2.

8. An electronic device, comprising:
at least one heat generating source; and
at least one heat dissipation structure, the at least one heat dissipation structure including a first plate body, a second plate body, and m thermally conductive members, and one end of at least one of the m thermally conductive members is arranged adjacent to the at least one heat generating source;
wherein the m thermally conductive members are disposed between the first plate body and the second plate body;
wherein n thermally conductive members of the m thermally conductive members are arranged along at least one of a length direction of the first plate body and a length direction of the second plate body, and a width direction of the first plate body and a length direction of the second plate body, and m≥n≥2.

9. The electronic device according to claim 8, wherein the at least one heat generating source is a central processing unit (CPU), a graphics processing unit (GPU), a microcontroller (MCU), a microprocessor (MPU), or an application specific integrated circuit (ASIC).

10. The electronic device according to claim 8, further comprising:
at least one heat dissipation member, wherein another end of the at least one of the m thermally conductive members is connected to the at least one heat dissipation member.
